(19) United States
(12) Patent Application Publication
(10) Pub. No.: US 2022/0413236 A1
(43) Pub. Date: Dec. 29, 2022

(54) PHOTONIC INTEGRATED CIRCUIT COOLING WITH A THERMAL DIE

(71) Applicant: Intel Corporation, Santa Clara, CA (US)

(72) Inventors: Omkar KARHADE, Chandler, AZ (US); Sushrutha Reddy GUJJULA, Chandler, AZ (US); Tolga ACIKALIN, San Jose, CA (US); Ravindranath V. MAHAJAN, Chandler, AZ (US); James E. JAUSSI, Hillsboro, OR (US); Chia-Pin CHIU, Tempe, AZ (US)

(21) Appl. No.: 17/358,502

(22) Filed: Jun. 25, 2021

(51) Int. Cl. G02B 6/42; H01L 25/16; H01L 23/00; H01L 23/367; H01S 3/04

(52) U.S. Cl. CPC G02B 6/4268; H01L 25/167; H01L 24/16; H01L 23/3672; G02B 6/4274; H01S 3/0405; H01L 2224/16145; H01L 2224/16227

(57) ABSTRACT

Embodiments described herein may be related to apparatuses, processes, and techniques related to thermally and/or electrically coupling a thermal die to the surface of a photonic integrated circuit (PIC) within an open cavity in a substrate, where the thermal die is proximate to a laser on the PIC. Other embodiments may be described and/or claimed.

### FIELD

Embodiments of the present disclosure generally relate to the field of semiconductor packaging, and in particular photonic integrated circuits (PIC).

### BACKGROUND

Continued growth in computing and mobile devices will continue to increase the demand for increased bandwidth density between dies within semiconductor packages.

### BRIEF DESCRIPTION OF THE DRAWINGS

FIG. 1 illustrates a block diagram of a legacy package that includes a photonics integrated circuit (PIC) placed within a substrate cavity.

FIG. 2 illustrates a block diagram of a legacy package that includes a plurality of open cavity PICs in a substrate that are coupled with a plurality of dies.

FIG. 3 illustrates a cross-section front view and a cross section side view of an open cavity PIC coupled with a thermal/power die and an integrated heat spreader, in accordance with various embodiments.

FIG. 4 illustrates a block diagram of a package that includes a plurality of open cavity PICs in a substrate that are coupled with a plurality of thermal/power dies and a plurality of other dies, in accordance with various embodiments.

FIGS. 5A-5F illustrate example stages in a process to manufacture a package that includes an open cavity PIC in a substrate coupled with a thermal/power die and another die, in accordance with various embodiments.

FIG. 6 illustrates an example of a process for coupling an open cavity PIC with a thermal/power die, in accordance with various embodiments.

FIG. 7 schematically illustrates a computing device, in accordance with various embodiments.

### DETAILED DESCRIPTION

Embodiments described herein may be related to apparatuses, processes, and techniques related to thermally and/or electrically coupling a thermal die to the surface of a PIC within an open cavity proximate to a laser on the PIC. As used herein, a PIC within an open cavity may be referred to as an open cavity PIC. The thermal die may be used transfer heat from a hottest portion of the PIC, which may be near the laser, through the thermal die to an integrated heat spreader. The thermal die may also be used to electrically couple the PIC to a power source on the substrate. In other embodiments, another die such as an XPU, an electric IC (EIC), or an input/output (I/O) hub may also be electrically coupled with the open cavity PIC. The thermal die and the other die may also be thermally coupled with an integrated heat spreader (IHS).

Optical interconnects offer very high bandwidths compared to electrical interconnects. PICs are used to convert electrical signal to optical signals and vice versa. PICs implemented within open cavities of a substrate have an advantage of providing a direct PIC to EIC connection for better power efficiency, clean access for fiber attach at an opposite end of the PIC, and access to thermal hotspots on PIC for cooling the PIC during operation.

PICs have lasers, which may be referred to as lasing components, as well as amplifiers and/or other electrical circuits which generate significant power densities, for example 50 W-150 W/mm², compared to a legacy central processing unit (CPU) that may have 5 W-50 W/mm² power density depending on use. Optical components such as lasers can typically only tolerate a lower maximum temperature, for example ˜70-90° C. compared to the maximum junction temperatures on a XPU chip which may be, for example ˜100-110° C. Hence, cooling legacy PICs implementations is a challenge. In addition, in open cavity PIC implementations, the PIC has an active layer on top and the PIC is not directly electrically coupled with power on the substrate at a bottom of the cavity in which the PIC may be placed. As a result, power delivery for legacy PIC implementations is challenging.

In embodiments described herein, for open cavity PIC implementations, a thermally conductive/power delivery die, which may be referred to as a thermal die, is connected to a top of the PIC and to a top of the substrate to supply power from the substrate to the PIC. The thermally conductive/power delivery die may thermally connect to a heatsink on the top side of the package to provide a heat dissipation path for the PIC, and in particular for the heat generated by the laser element of the PIC. In embodiments, thermally conductive solder joints and/or copper pillars may provide a thermal path between the PIC and the thermally conductive/power delivery die. In addition, standard thermal interface materials may be used for heat transfer between the thermally conductive/power delivery die and the integrated heat spreader for the package.

Embodiments described herein allow power delivery to be provided to a PIC by electrically coupling the substrate to the PIC using the thermal die, and the PIC maybe cooled by the thermal die by thermally coupling the thermal die to a IHS. In addition, in embodiments, because power delivery and signal routing may be from a single surface of the thermal die, through silicon vias (TSV) in the PIC die are not required for power or signal routing. In addition, embodiments eliminate the need for wire bonding, which increases package reliability.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

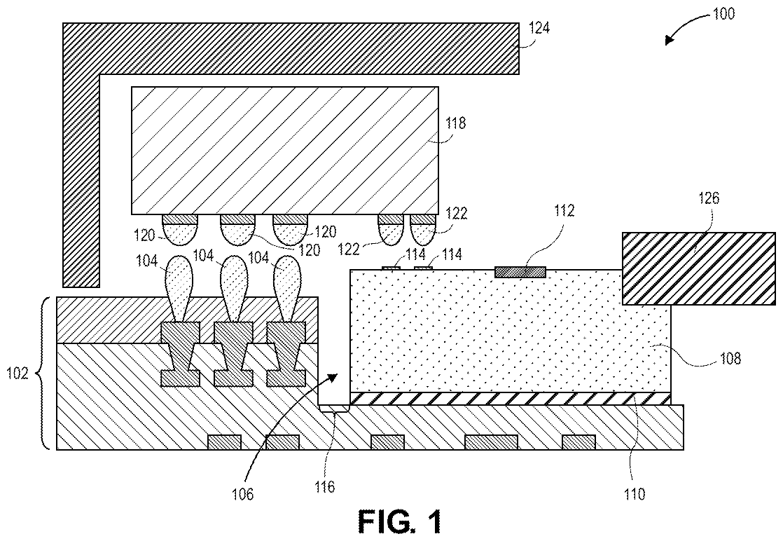

FIG. 1 illustrates a block diagram of a legacy package that includes a photonics integrated circuit (PIC) placed within a substrate cavity. Legacy package 100 shows an open cavity PIC schematic that includes a substrate 102 with a first set of bumps 104 at a top side of the substrate 102. A cavity 106 has been removed from the substrate 102, into which a PIC 108 has been inserted. The PIC 108 may be coupled to the bottom of the cavity 106 using a solder 110, or some other adhesive material.

The top side of the PIC 108 may include one or more laser elements, as well as one or more electrical connectors 114 positioned at the top of the PIC 108 and close to the substrate bumps 104. Due to the cavity 106 manufacturing process, there is a gap 116 between an edge of the PIC 108 and an edge of the substrate 102 based upon the manufacturing methods of the cavity 106.

An electronic integrated circuit (EIC) 118 is physically and electrically coupled with the substrate 102 and the PIC 108. In particular, EIC 118 bumps 120 couple with substrate 102 bumps 104, and EIC 118 bumps 122 are to couple with PIC 108 electrical connectors 114. The PIC 108 is only coupled with the substrate 102 via the EIC 118. An integrated heat spreader (IHS) 124 is thermally coupled with the substrate 102, with the EIC 118, and with other components of the package (not shown). A fiber attach 126 may be coupled with a side of the PIC 108, and may use a V-groove fiber alignment.

Optical interconnects offer very high bandwidths compared to electrical interconnects. Photonic ICs (PIC) are used within semiconductor packages to convert electrical signal to optical signals and vice versa. Open cavity based integration of PICS offers direct PIC to EIC electrical and physical connection for better power efficiency, clean access for fiber attach and access to hotspots on PIC for cooling. PICS have lasing components, such as laser 112, which are sensitive to mechanical stresses that result from heat generation during PIC operation.

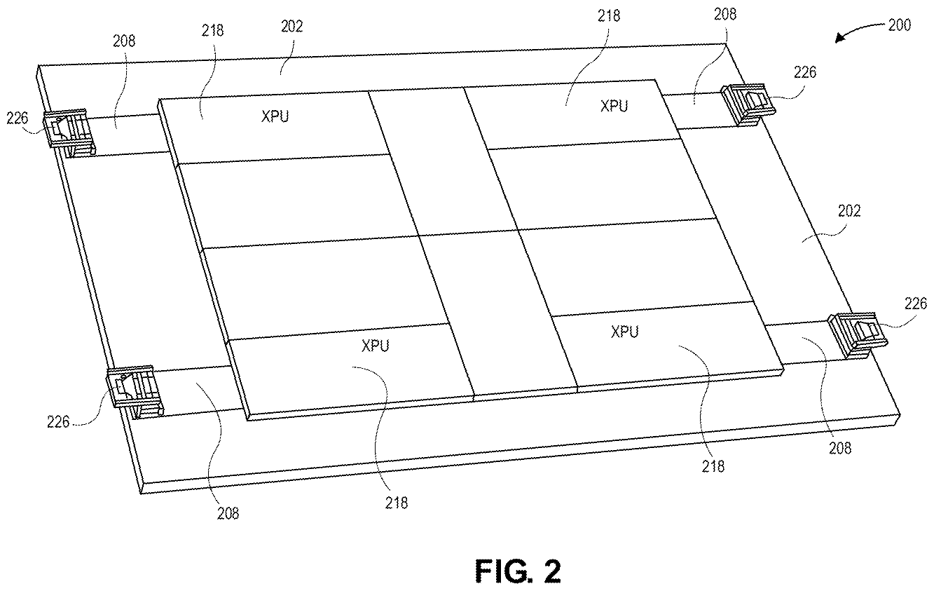

FIG. 2 illustrates a block diagram of a legacy package that includes a plurality of open cavity PICS in a substrate that are coupled with a plurality of dies. Legacy package 200 includes a substrate 202, with multiple PIC 208 embedded within cavities, similar to cavity 108, within the substrate 202. The multiple PIC 208 are also coupled with one or more XPU dies 218. Multiple fiber attaches 226 are optically and physically coupled, respectively, with the multiple PIC 208. These may be similar to substrate 102, PIC 108, EIC 118, and fiber attach 126 of FIG. 1. In other implementations, the XPU 218 may be a computer die, an EIC, or some other die that is electrically coupled with the PIC 208.

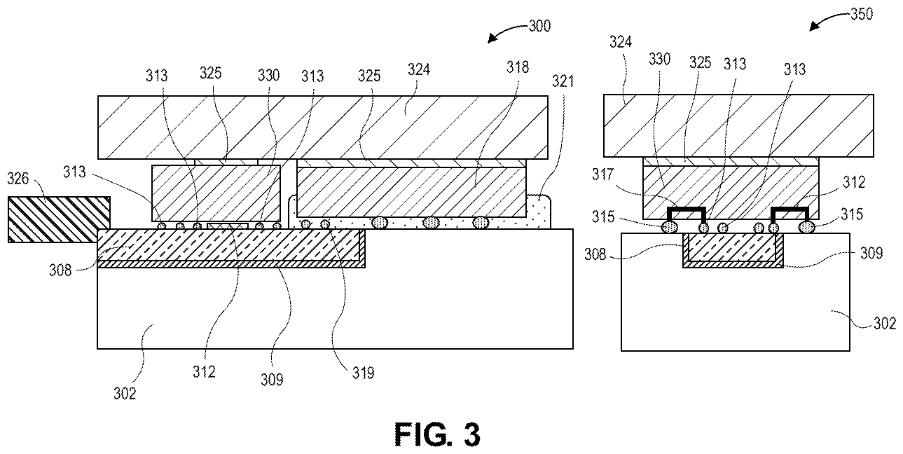

FIG. 3 illustrates a cross-section front view and a cross section side view of an open cavity PIC coupled with a thermal/power die and an integrated heat spreader, in accordance with various embodiments. FIG. 3 includes a front view cross-section 300, and side view cross-section 350 of an embodiment of a thermal die thermally and/or electrically coupled with a PIC 308.

In embodiments, PIC 308, which may be referred to as an open cavity PIC 308, is recessed within a cavity of the substrate 302. In embodiments, and underfilling 309 may be used to secure the PIC 308 in place. The PIC 308 may include a laser element 312 that is disposed at or near a top surface of the PIC 308. In embodiments, one or more thermally and/or electrically conductive joints 313 may thermally and/or electrically couple the PIC 308 with a thermal die 330. In embodiments, joints 313 may include solder joints and/or copper pillars.

The thermal die 330 may be placed proximate to, or directly over, the laser element 312. In embodiments, the laser element 312 or circuitry (not shown) proximate to the laser element 312 may be a major source of heat generated during operation of the PIC 308. The placement of the joints 313, as well as the placement of the thermal die 330 may be based on locations within the PIC 308 that are generating heat during operation. In particular, the joints 313 may be placed close to the source of heat, with the thermal die 330 placed directly over the laser element 312.

In embodiments, the volume between the thermal die 330 and the PIC 308, particularly around the laser element 312, may not include any underfill and may be only air to prevent mechanical stress to the laser element 312 during operation.

As shown with respect to side view cross-section 350, one or more of the joints 313 may electrically couple with one or more electrical contacts 315 on the substrate 302. Some of these electrical contacts 315 may be power contacts use to supply power to the PIC 308. In embodiments, conductive traces 317, which may include conductive vias, within the thermal die 330 may be used to route power between the electrical contacts 315 and the PIC 308. As shown, a width of the thermal die 330 may be greater than the width of the PIC 308 within the substrate 302, in order for the thermal die 330 to electrically couple with elements on the substrate 302.

A fiber attach 326, which may be similar to fiber attach 126 of FIG. 1, is optically and physically coupled with the PIC 308. In embodiments, the fiber attach 326 may be a V-groove structure or some other optical connect structure, for example a lens-based fiber coupling, or a collimated and/or expanded beam fiber coupling.

In addition an XPU 318 may be physically and/or electrically coupled with the PIC 308 and with the substrate 302. In embodiments, during operation, the PIC 308 would receive optical signals from the fiber attach 326, and process them into electric signals using power from the top of the substrate 302 provided by the thermal die 330, and then transmit those electrical signals through electrical connections 319 to the XPU 318. In embodiments, the XPU 318 may be a compute die, a CPU, a GPU, a die complex field programmable gate array (FPGA), network interface card (NIC), or some other component to receive and process electrical signals from the PIC 308. During operation, the XPU 318 generates heat as it processes the signals received from the PIC 308.

In embodiments, the top of the XPU 318 and the thermal die 330 may be thermally coupled with an integrated heat spreader (IHS) 324 to route heat away from the PIC 308 and the XPU 318. In embodiments, a thermal interface material (TIM) 325 may be placed between the PIC 308 and the IHS 324, and between the XPU 318 and the IHS 324 to facilitate thermal routing. In embodiments, the volume between the substrate 302 and the XPU 318, as well as a volume around the XPU 318 may include an underfill 321. Additionally, the thermal die 330 may provide mechanical and structural rigidity to the PIC 308 and the package 300 overall, which will increase reliability and minimize warpage, that can be an important factor for the fiber attach 326 attachment integrity.

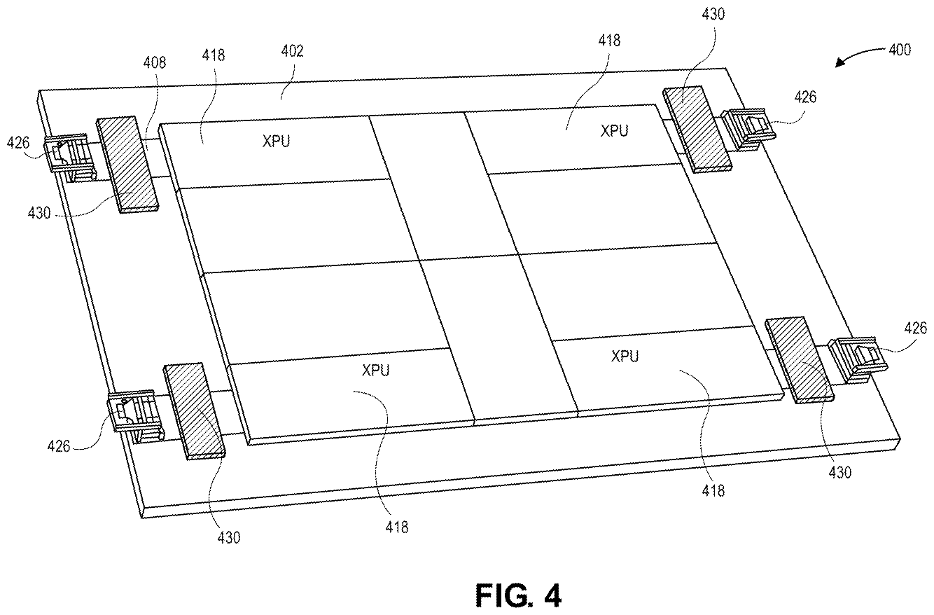

FIG. 4 illustrates a block diagram of a package that includes a plurality of open cavity PICs in a substrate that are coupled with a plurality of thermal/power dies and a plurality of other dies, in accordance with various embodiments. Package 400, which may be similar to package 200 of FIG. 2, includes a substrate 402, with multiple PIC 408 embedded within cavities, similar to cavity 106 of FIG. 1, within the substrate 402. The multiple PIC 408 are also coupled with one or more XPU dies 418. Multiple fiber attaches 426 are optically and physically coupled, respectively, with the multiple PIC 408. These may be similar to substrate 302, PIC 308, XPU 318, and fiber attach 326 of FIG. 3.

A multiple thermal dies 430, which may be similar to thermal die 330 of FIG. 3, may be placed on top of, respectively, multiple PICs 408. Note that in package 400 the IHS 324 is not shown for clarity. In embodiments (not shown), the fiber attach 426/PIC 408/thermal die 430 combination may be placed in any location within the substrate 402, or at any edge location of the substrate 402.

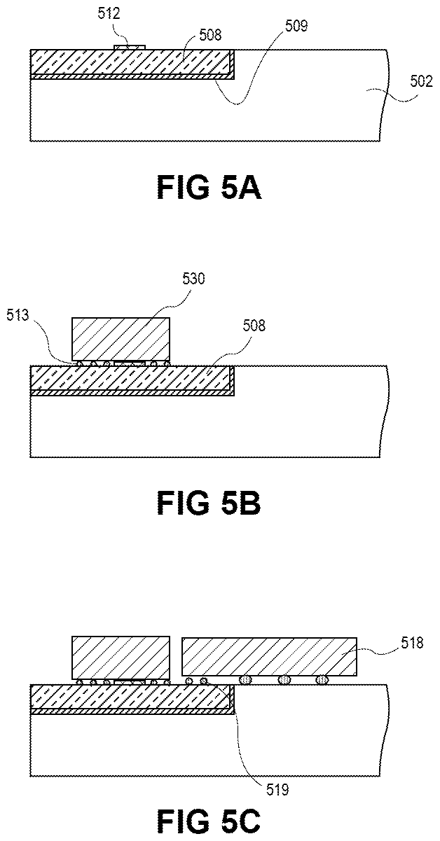

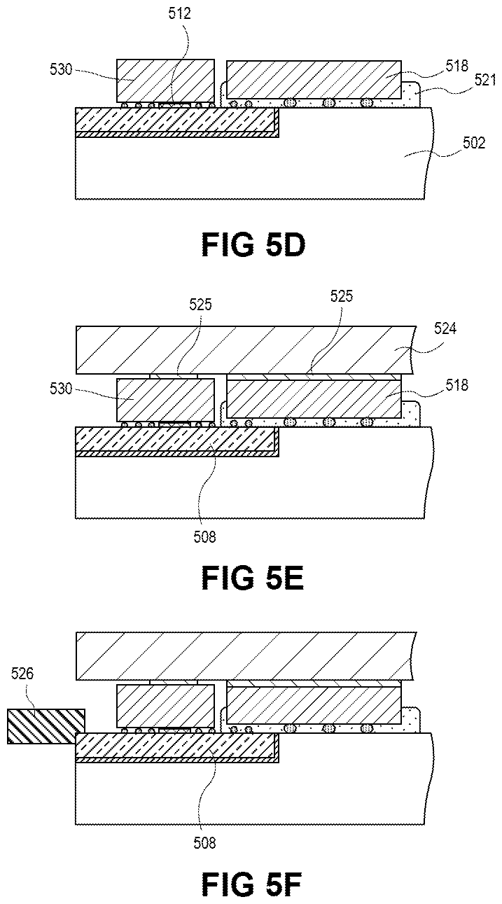

FIGS. 5A-5F illustrate example stages in a process to manufacture a package that includes an open cavity PIC in a substrate coupled with a thermal/power die and another die, in accordance with various embodiments.

FIG. 5A shows a substrate 502, which may be similar to substrate 302 of FIG. 3, with a PIC 508, which may be similar to PIC 308 of FIG. 3, embedded within a cavity of the substrate 502. In embodiments, the PIC 508 may be surrounded by an underfill material 509, which may be similar to underfill material 309 of FIG. 3. A laser element 512, which may be similar to laser element 312 of FIG. 3, may be coupled to a surface of the PIC 508. In embodiments, the underfill material 509 will help secure the PIC 508 to the substrate 502, and to provide additional structural rigidity to the PIC 508 to prevent warping due to thermal energy generated during operation.

FIG. 5B shows a thermal die 530, which may be similar to thermal die 330 FIG. 3, thermally and/or electrically coupled with the PIC 508. In embodiments, one or more thermally and/or electrically conductive joints 513, which may be similar to joints 313 of FIG. 3, may thermally and/or electrically couple the PIC 508 with a thermal die 530. Note that in some embodiments, the joints 513 may be dummy joints that do not carry electrical current, but rather are thermal joints to route thermal energy from the PIC 508 to the thermal die 530.

FIG. 5C shows an XPU 518, which may be similar to XPU 318 of FIG. 3, that is physically and/or electrically coupled with the PIC 508 and the substrate 502. In embodiments, one or more conductive joints 519 may be used to perform the physical and/or electrical coupling.

FIG. 5D shows an underfill 521, which may be similar to underfill 321 of FIG. 3, that is placed within a volume between the XPU 518 and the substrate 502, as well as other volume surrounding the XPU 518. Note that in embodiments, the underfill 521 does not flow under the thermal die 530, so that the laser element 512 is not covered or blocked by the underfill. In embodiments, the laser element 512 may be covered or blocked or protected by some other physical means, such that underfill 521 may flow over the PIC 308, and the laser element 512 covering or blocking may subsequently be removed.

FIG. 5E shows a thermal interface material (TIM) 525, which may be similar to TIM 325 of FIG. 3, applied to a top surface of the thermal die 530 and to a top surface of the XPU 518. In addition, an integrated heat spreader (IHS) 524, which may be similar to IHS 324 of FIG. 3, is thermally coupled with the TIM 525 and thus with the thermal die 530 and the XPU 518.

FIG. 5F shows a fiber attach 526, which may be similar to fiber attach 326 of FIG. 3, optically and physically coupled with the PIC 508.

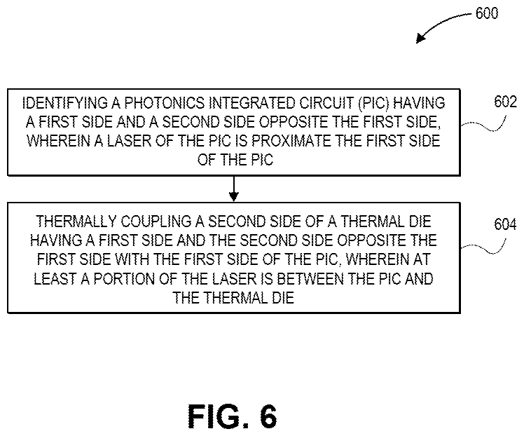

FIG. 6 illustrates an example of a process for coupling an open cavity PIC with a thermal/power die, in accordance with various embodiments. Process 600 may be performed using the techniques, methods, systems, and/or apparatus as described with respect to FIGS. 1-5F.

At block 602, the process may include identifying a photonics integrated circuit (PIC) having a first side and a second side opposite the first side, wherein a laser of the PIC is proximate to the first side of the PIC.

At block 604, the process may further include thermally coupling a second side of a thermal die having a first side and the second side opposite the first side with the first side of the PIC, wherein at least a portion of the laser is between the PIC and the thermal die.

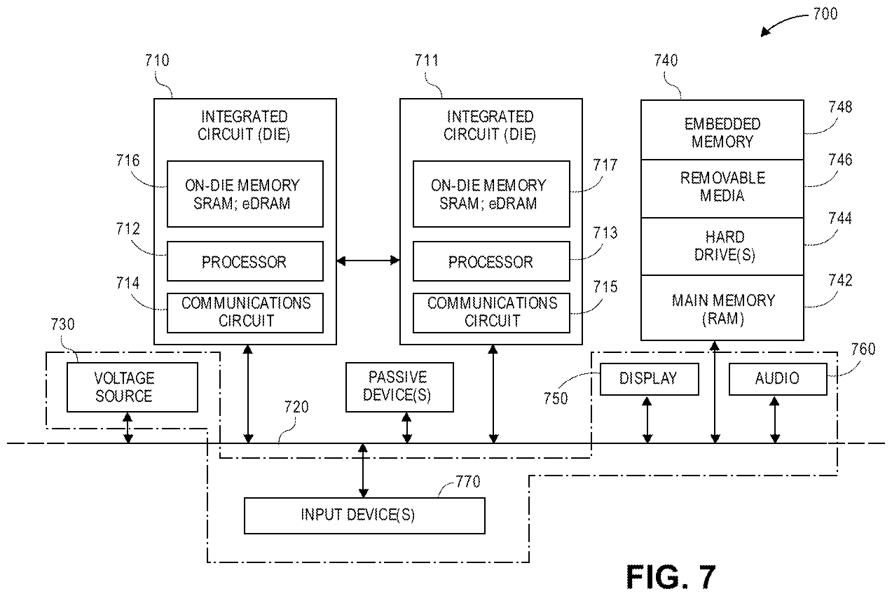

FIG. 7 schematically illustrates a computing device, in accordance with various embodiments. FIG. 7 is a schematic of a computer system 700, in accordance with an embodiment of the present invention. The computer system 700 (also referred to as the electronic system 700) as depicted can embody photonic integrated circuit cooling with a thermal die, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, photonic integrated circuit cooling with a thermal die, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having photonic integrated circuit cooling with a thermal die, according to any of the several disclosed embodiments and their equivalents, an electronic system, a computer system, one or more methods of fabricating an integrated circuit, and one or more methods of fabricating an electronic assembly that includes a package substrate having photonic integrated circuit cooling with a thermal die, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having photonic integrated circuit cooling with a thermal die embodiments and their equivalents. A foundation substrate may be included, as represented by the dashed line of FIG. 7. Passive devices may also be included, as is also depicted in FIG. 7.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a package comprising: a photonics integrated circuit (PIC) having a first side and a second side opposite the first side, wherein a laser of the PIC is proximate to the first side of the PIC; and a thermal die having a first side and a second side opposite the first side, the second side thermally coupled with the first side of the PIC, wherein at least a portion of the laser is between the PIC and the thermal die.

Example 2 includes the package of example 1, wherein the second side of the thermal die and the first side of the PIC are thermally coupled using a selected one of: solder joints or copper pillars.

Example 3 includes the package of example 2, wherein the selected one of the solder joints or the copper pillars are located on the first side of the PIC in a location proximate to the laser.

Example 4 includes the package of example 1, wherein a volume between the laser and the second side of the thermal die does not include an underfill.

Example 5 includes the package of example 1, wherein the second side of the thermal die is electrically coupled with the first side of the PIC.

Example 6 includes the package of example 1, further comprising a thermal interface material thermally coupled with the first side of the thermal die.

Example 7 includes the package of example 1, wherein the first side of the PIC has a first width and wherein the second side of the thermal die has a second width; and wherein the second width is greater than the first width.

Example 8 includes the package of any one of examples 1-7, wherein the thermal die is a selected one of: a silicon die, a gallium nitride (GaN) die, a silicon carbide (SiC) die, a diamond die, any III-V die, a germanium die, a sapphire die, or a sapphire on silicon die.

Example 9 is a method comprising: identifying a photonics integrated circuit (PIC) having a first side and a second side opposite the first side, wherein a laser of the PIC is proximate the first side of the PIC; and thermally coupling a second side of a thermal die having a first side and the second side opposite the first side with the first side of the PIC, wherein at least a portion of the laser is between the PIC and the thermal die.

Example 10 includes the method of example 9, further comprising, before identifying the PIC: placing the PIC within an open cavity of a substrate.

Example 11 includes the method of example 10, wherein the open cavity is at an edge of the substrate.

Example 12 includes the method of any one of examples 9-11, wherein thermally coupling the second side of the thermal die with the first side of the PIC further includes electrically coupling the second side of the thermal die with the first side of the PIC.

Example 13 is a package comprising: a substrate with an open cavity at an edge of the substrate; a photonics integrated circuit (PIC) located within the open cavity of the substrate, the PIC having a first side and a second side opposite the first side, wherein a laser of the PIC is proximate to the first side of the PIC, and wherein the second side of the PIC is physically coupled with the substrate; a thermal die having a first side and a second side opposite the first side, the second side thermally and electrically coupled with the first side of the PIC, wherein at least a portion of the laser is located under the thermal die.

Example 14 includes the package of example 13, wherein the second side of the thermal die is electrically and physically coupled with the substrate.

Example 15 includes the package of example 14, wherein the second side of the thermal die is electrically coupled with a power source on the substrate.

Example 16 includes the package of example 13, wherein the second side of the thermal die and the first side of the PIC are thermally or electrically coupled using a selected one of: solder joints or copper pillars.

Example 17 includes the package of example 13, further comprising another die having a first side and a second side opposite the first side, the second side of the other die physically and electrically coupled with the first side of the PIC.

Example 18 includes the package of example 17, further comprising a thermal interface material thermally coupled with the first side of the thermal die and the first side of the other die.

Example 19 includes the package of example 18, further comprising an integrated heat spreader (IHS) physically and thermally coupled to the thermal interface material coupled with the first side of the thermal die and the thermal interface material coupled with the first side of the other die.

Example 20 includes the package of any one of examples 13-19, wherein the other die is a selected one of: an XPU, a central processing unit (CPU), a graphics processing unit (GPU), an electric integrated circuit (EIC), or an input/output (I/O) hub.

Example 21 includes the package of any one of examples 13-19, wherein the PIC includes a fiber attach.

Example 22 includes the package of any one of examples 13-19, wherein a volume between the laser and the second side of the thermal die does not include an underfill.

What is claimed is:

1. A package comprising:
a photonics integrated circuit (PIC) having a first side and a second side opposite the first side, wherein a laser of the PIC is proximate to the first side of the PIC; and
a thermal die having a first side and a second side opposite the first side, the second side thermally coupled with the first side of the PIC, wherein at least a portion of the laser is between the PIC and the thermal die.

2. The package of claim 1, wherein the second side of the thermal die and the first side of the PIC are thermally coupled using a selected one of: solder joints or copper pillars.

3. The package of claim 2, wherein the selected one of the solder joints or the copper pillars are located on the first side of the PIC in a location proximate to the laser.

4. The package of claim 1, wherein a volume between the laser and the second side of the thermal die does not include an underfill.

5. The package of claim 1, wherein the second side of the thermal die is electrically coupled with the first side of the PIC.

6. The package of claim 1, further comprising a thermal interface material thermally coupled with the first side of the thermal die.

7. The package of claim 1, wherein the first side of the PIC has a first width and wherein the second side of the thermal die has a second width; and wherein the second width is greater than the first width.

8. The package of claim 1, wherein the thermal die is a selected one of: a silicon die, a gallium nitride (GaN) die, a silicon carbide (SiC) die, a diamond die, any III-V die, a germanium die, a sapphire die, or a sapphire on silicon die.

9. A method comprising:
identifying a photonics integrated circuit (PIC) having a first side and a second side opposite the first side, wherein a laser of the PIC is proximate the first side of the PIC; and
thermally coupling a second side of a thermal die having a first side and the second side opposite the first side with the first side of the PIC, wherein at least a portion of the laser is between the PIC and the thermal die.

10. The method of claim 9, further comprising, before identifying the PIC: placing the PIC within an open cavity of a substrate.

11. The method of claim 10, wherein the open cavity is at an edge of the substrate.

12. The method of claim 9, wherein thermally coupling the second side of the thermal die with the first side of the PIC further includes electrically coupling the second side of the thermal die with the first side of the PIC.

13. A package comprising:
a substrate with an open cavity at an edge of the substrate;
a photonics integrated circuit (PIC) located within the open cavity of the substrate, the PIC having a first side and a second side opposite the first side, wherein a laser of the PIC is proximate to the first side of the PIC, and wherein the second side of the PIC is physically coupled with the substrate;
a thermal die having a first side and a second side opposite the first side, the second side thermally and electrically coupled with the first side of the PIC, wherein at least a portion of the laser is located under the thermal die.

14. The package of claim 13, wherein the second side of the thermal die is electrically and physically coupled with the substrate.

15. The package of claim 14, wherein the second side of the thermal die is electrically coupled with a power source on the substrate.

16. The package of claim 13, wherein the second side of the thermal die and the first side of the PIC are thermally or electrically coupled using a selected one of: solder joints or copper pillars.

17. The package of claim 13, further comprising another die having a first side and a second side opposite the first side, the second side of the other die physically and electrically coupled with the first side of the PIC.

18. The package of claim 17, further comprising a thermal interface material thermally coupled with the first side of the thermal die and the first side of the other die.

19. The package of claim 18, further comprising an integrated heat spreader (IHS) physically and thermally coupled to the thermal interface material coupled with the first side of the thermal die and the thermal interface material coupled with the first side of the other die.

20. The package of claim 13, wherein the other die is a selected one of: an XPU, a central processing unit (CPU), a graphics processing unit (GPU), an electric integrated circuit (EIC), or an input/output (I/O) hub.

21. The package of claim 13, wherein the PIC includes a fiber attach.

22. The package of claim 13, wherein a volume between the laser and the second side of the thermal die does not include an underfill.
